(19) United States
(12) Patent Application Publication
(10) Pub. No.: US 2026/0290143 A1
(43) Pub. Date: Sep. 24, 2026

(54) HEATSINK OBSTRUCTION DETECTION SYSTEM

(71) Applicant: SIGNIFY HOLDING B.V., EINDHOVEN (DE)

(72) Inventor: KHURRAM ZESHAN MOGHAL, SENOIA, GA (US)

(21) Appl. No.: 19/168,913

(22) PCT Filed: Mar. 20, 2024
(86) PCT No.: PCT/EP2024/057459

§ 371 Date: Sep. 25, 2025

Related U.S. Application Data
(60) Provisional application No. 63/455,135, filed on Mar. 28, 2023.

(30) Foreign Application Priority Data
May 11, 2023 (EP) 23172838.7

(51) Int. Cl. G08B 21/18; F21V 29/74

(52) U.S. Cl. CPC G08B 21/182; F21V 29/74

(57) ABSTRACT

A heat-dissipating obstruction detection system for detecting an obstruction or the accumulation of dust on a heatsink (or its fins) in an air-cooled luminaire or hardware device, including one or more sensors, coupled to the heat sink's fins, wherein the sensors send infrared beams that reflect off the fins of the heatsink surface and the reflection is then received/detected by the sensors; a control device to determine an obstruction level on the heatsink using the sensor reflection information; if the obstruction level of the heat sink exceeds an obstruction threshold, an alert is generated that can be sent to a user, the alert also includes a signal to an active cooling device to increase the active cooling. The heat-dissipating obstruction detection system also sends a second alert the user to service the device, for example a lighting fixture, coupled to the heat sink when the obstruction/debris has reached beyond the point where it cannot be removed or cleaned by the active cooling device.

### FIELD OF THE INVENTION

The present invention relates generally to a computer implemented method, a data processing system, and a sensor detection system. More specifically, the present invention relates to a heat-dissipating/heatsink obstruction detection system for identifying debris build up within the heat sink with active/passive cooling elements of Light-Emitting Diodes (LEDs) circuit or other integrated circuit.

Light-emitting diodes (LEDs) have the advantages of providing a bright light, being reasonably inexpensive, having a long operational life, and drawing very little power. Accordingly, LEDs are increasingly employed for a variety of illumination applications as an alternative to other forms of lighting, such as incandescent, halogen, etc.

As part of the luminaire manufacturing or assembly process, it is often necessary to provide a heatsink over the LED board, to prevent the degradation or destruction of the LEDs and other electronic components. Traditional heat sinks typically have fins for dissipating heat into the environment surrounding the heat sink. Traditional heat sinks absorb the heat from a LEDs and transfer the heat throughout the heat-dissipating fins using thermal conduction.

These cooling solutions may also include active cooling fans to channel air over the heatsink in order to move a high quantity of air to maximize the cooling effectiveness. However, the reliability of fans have been a concern in active cooling applications which has hampered the use of fans in industry.

In some environments, there have been issues associated with heat sinks clogging up with dirt, dust and lint that is carried into the system by the fan. The accumulation of dust in a luminaire or other device can cause problems, for example from dirt, debris, frost/ice, bird nest etc. Excessive dust build-up can reduce system performance, increase the rate at which the LEDs, LED drivers or other components to fail, and reduce overall system reliability.

The amount of dust that accumulates in a luminaire is typically not apparent without removing it and opening it up. Manually inspecting for dust is inefficient, usually necessitating the removal of the housing of a luminaire. An improved dust detection system and method are therefore needed.

### BACKGROUND OF THE INVENTION

The present disclosure is directed to an apparatus and a method for detecting an obstruction such as dust within an electronic system, such as within a luminaire.

An embodiment of a heat-dissipating obstruction detection system for detecting an obstruction or the accumulation of dust on a heatsink (or its fins) in an air-cooled luminaire or hardware device. The luminaire/device includes one or more sensors, such as “rain” sensors or optical electrical sensors, coupled to the heat sink's fins. The sensors (or other light source) send infrared beams that reflect off the fins of the heatsink surface and the reflection is then received/detected by the sensors. The heat-dissipating obstruction detection system includes a control unit to determine an obstruction on the heatsink using the sensor reflection information. If the obstruction level of the heat sink exceeds an obstruction threshold, an alert is generated. The alert may be a signal to control center or user site indicating service is needed or it can be a light/visual indicator on luminaire itself. The heat-dissipating obstruction detection system further includes an active cooling device, such as a fan, to actively cool the heatsink. The control device is configured to send a signal to the active cooling device to increase the active cooling, for example, to the fan to throttle up the speed to maintain the effectivity of advanced cooling. The active cooling device/fan can automatically adjust to different speeds according to the amount of obstruction/debris accumulated. The heat-dissipating obstruction detection system also sends a second alert to the user to service the device, for example a lighting fixture, coupled to the heat sink when the obstruction/debris has reached beyond the point where it cannot be removed or cleaned by the active cooling device (e.g. fan).

US 2010/169046 A1 relates to identifying blockages in a heat sink of a data processing system. An electromagnetic emitter and an electromagnetic detector are positioned on opposite sides of the heat sink. An intensity of a stream of electromagnetic radiation directed from the electromagnetic emitter is measured by the electromagnetic detector. Based on the measured intensity of the stream of electromagnetic radiation as measured by the electromagnetic detector, a blockage level of the heat sink is determined. If the blockage level of the heat sink exceeds a blockage threshold, an alert is generated.

US 2008/246624 A1 relates to a heat-dissipating system configured to dissipate heat from an electrical device, includes a heat sink having a plate on which dust is likely to accumulate if dust is present, a light-emitting element arranged on the plate of the heat sink, and an alarm. The alarm device is arranged on the plate of the heat sink and configured to receive light from the light-emitting element. If dust accumulates on the plate thick enough to block light so that the alarm device cannot receive light from the light-emitting element, the alarm device will activate.

US 2019/235982 A1 relates to detecting impaired flow of cooling air within a chassis enclosure of an information handling system during system operation, and to implement a diagnostic or system boot mode to reverse direction of cooling air flow through the chassis enclosure after such detection of impeded cooling air flow so as to remove any dust or other accumulated debris that is causing the impeded cooling air flow.

### BRIEF DESCRIPTION OF THE DRAWINGS

Features of the present disclosure are illustrated by way of example and not limited in the following figure(s), in which like numerals indicate like elements.

FIG. 1 is top perspective views of a heat-dissipating obstruction detection system, according to an embodiment of the present disclosure;

FIG. 2 is a top view of the heat-dissipating obstruction detection system of FIG. 1;

FIG. 3 is bottom perspective views of a heat-dissipating obstruction detection system, according to an embodiment of the present disclosure;

FIG. 4 is a lighting device/luminaire to which the heat-dissipating obstruction detection system is coupled to.

FIG. 5 is a flow generally outlining a method of a heat-dissipating obstruction detection, according to an embodiment of the present disclosure.

### DETAILED DESCRIPTION

For simplicity and illustrative purposes, the present disclosure is described by referring mainly to an example thereof. In the following description, numerous specific details are set forth in order to provide a thorough understanding of the present disclosure. However, the present disclosure may be practiced without limitation to these specific details. In other instances, some methods and structures have not been described in detail so as not to unnecessarily obscure the present disclosure.

The elements depicted in the accompanying figures may include additional components and that some of the components described in those figures may be removed and/or modified without departing from scopes of the elements disclosed herein. The elements depicted in the figures may not be drawn to scale and thus, the elements may have different sizes and/or configurations other than as shown in the figures.

The examples discussed hereinafter will focus on the implementation of the hereinafter-described apparatus and techniques within LED applications. However, it will be appreciated that the apparatus and techniques may also be used in connection with other applications in different technology fields.

As will be appreciated by one skilled in the art, the present invention may be embodied as a system, method, or computer program product. Accordingly, the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, the present invention may take the form of a computer program product embodied in any tangible medium of expression having computer usable program code embodied in the medium.

Any combination of one or more computer usable or computer readable medium(s) may be utilized. The computer-usable or computer-readable medium may be, for example but not limited to, an electronic, magnetic, optical, electromagnetic, infrared, or semiconductor system, apparatus, device, or propagation medium. More specific examples (a non-exhaustive list) of the computer-readable medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CDROM), an optical storage device, a transmission media such as those supporting the Internet or an intranet, or a magnetic storage device. Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer usable program code may be transmitted using any appropriate medium, including, but not limited to wireless, wireline, optical fiber cable, RF, etc.

The present invention is described below with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer program instructions.

These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer program instructions may also be stored in a computer-readable medium that can direct a computer or other programmable data processing apparatus to function in a particular manner, such that the instructions stored in the computer-readable medium produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide processes for implementing the functions/acts specified in the flowchart and/or block diagram block or blocks.

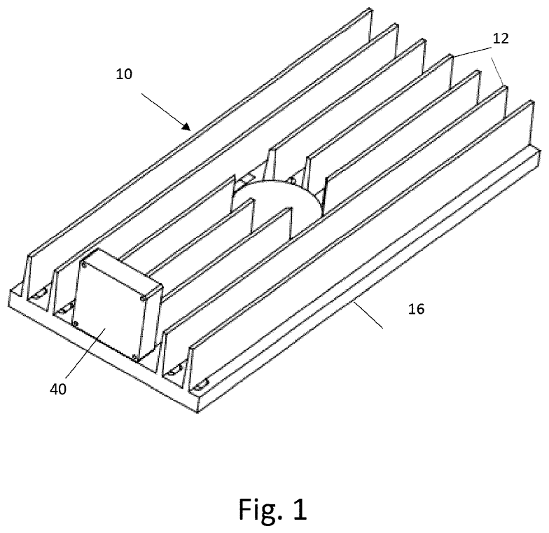

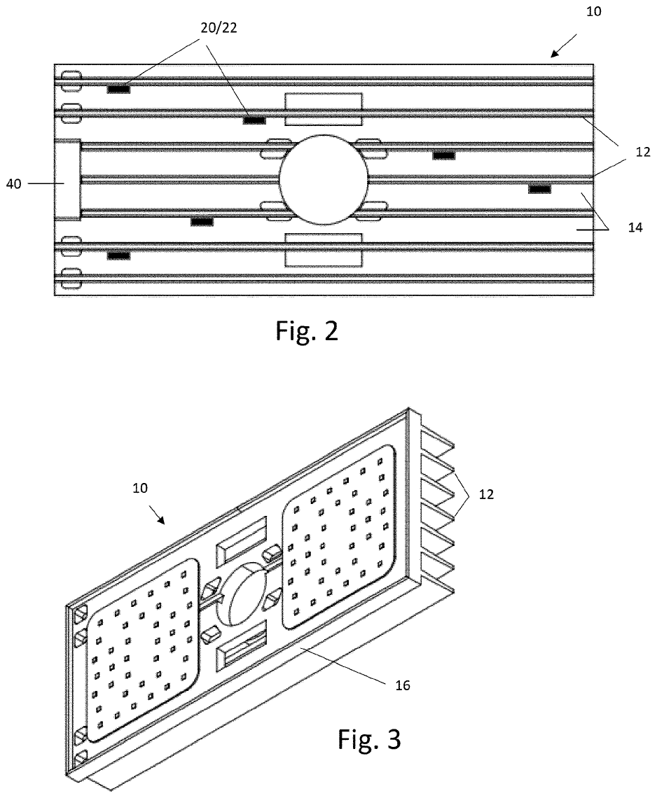

Turning now to FIGS. 1-4, a diagram of a data processing system is depicted in accordance with an illustrative embodiment.

Referring to FIGS. 1-4, a heat-dissipating obstruction detection system in accordance with an embodiment of the present invention is configured to dissipate heat from a heat-generating electrical device such as LEDs 18 or integrated circuit of an electrical device, etc. The heat-dissipating obstruction detection system includes a heat sink 10 having a heat-absorbing base plate 16 and a plurality of parallel fins 12 extending upright from the heat-absorbing base plate 16, one or more sensors 20, a control unit 30, and an active cooling unit 40, such as a controllable speed fan. A plurality of channels 14 are defined between two adjacent fins 12. The sensor 20 arranged at various locations on the fins 12 and in the channels 14.

Heat sink 10 is component designed to lower the temperature of an electronic device by dissipating heat into the surrounding air. Heat sink 10 can be an active heat sink, or a passive heat sink. Heat sink 10 can be made of for example, but not limited to, an aluminum alloy. Heat sink 10 comprises plurality of fins 12. Plurality of fins 12 are arranged so that the irrespective apertures align in a collinear manner. Heat sink 310 sits atop LEDs 18 or integrated circuit/printed circuit board (PCB) of an electrical device. Heat sink 310 helps to dissipate heat generated by LEDs 18 or integrated circuit.

During operation of a luminaire or system, dust, lint, dirt and other debris will routinely adhere to heat sink 10. This debris can impede airflow around the heat sink 10, negatively impacting cooling of LEDs (18) or integrated circuit. Overheating of the LEDs 18 or integrated circuit can in turn negatively impact performance of the system. The sensors 20 are mounted to various sections of the plurality of parallel fins 12, The sensors 20 transmits a light beam or signal and then measures the level of reflected light over the plurality of parallel fins 12 exterior surface to determine the amount of debris present. Alternatively (not shown), an additional light source can be mounted near the sensors 20 that can transmit the (infrared) light beam. The sensors 20 can be electro-optical sensors that convert light, or a change in light, into an electronic signal. They are used in many industrial and consumer applications, for example: Lamps that turn on automatically in response to darkness; Position sensors that activate when an object interrupts a light beam; Flash detection, to synchronize one photographic flash to another; Photoelectric sensors that detect the distance, absence, or presence of an object.

An optical sensor converts light rays into electronic signals. It measures the physical quantity of light and then translates it into a form that is readable by an instrument. An optical sensor is generally part of a larger system that integrates a source of light, a measuring device and the optical sensor. This is often connected to an electrical trigger. The trigger reacts to a change in the signal within the light sensor. An optical sensor can measure the changes from one or several light beams. When a change occurs, the light sensor operates as a photoelectric trigger and therefore either increases or decreases the electrical output. An optical switch enables signals in optical fibers or integrated optical circuits to be switched selectively from one circuit to another. An optical switch can operate by mechanical means or by electro-optic effects, magneto-optic effects as well as by other methods. Optical switches are optoelectronic devices which can be integrated with integrated or discrete microelectronic circuits.

The sensors 20 can one of several known optical sensors, including: photoconductive devices to convert a change of incident light into a change of resistance; photovoltaics, commonly known as solar cells, to convert an amount of incident light into an output voltage; photodiodes to convert an amount of incident light into an output current; and phototransistors a type of bipolar transistor where the base-collector junction is exposed to light. This results in the same behavior of a photodiode, but with an internal gain.

In addition, an adapted TRW Automotive Rain Sensor may be used. The TRW Automotive Rain Sensor is a fully automatic activated system that detects how hard rain or snow is falling. An infrared beam is reflected off the outside surface of the windshield to the infrared sensor array. When moisture strikes the windshield, the system experiences an interruption to its infrared beam. Advanced analog and digital signal processing determines the intensity of rain or snow. The control unit 30 serves to execute instructions for software that may be loaded into a memory, not shown. The control unit 30 may be a set of one or more processors or may be a multi-processor core, depending on the particular implementation. Further, the control unit 30 may be implemented using one or more heterogeneous processor systems in which a main processor is present with secondary processors on a single chip. As is known in the art the control unit 30 also may include a communications unit, not shown, to provide communications with other data processing systems or devices. The control unit 30 can also be integrated with sensor 20.

Instructions for the operating system and applications or programs are located the memory. These instructions may be loaded into the memory for execution by control unit 30. The processes of the different embodiments may be performed by control unit 30 using computer implemented instructions, which may be located in the memory. These instructions are referred to as program code, computer usable program code, or computer readable program code that may be read and executed by a processor in control unit 30. The program code in the different embodiments may be embodied on different physical or tangible computer readable media.

The illustrative embodiments provide a method, a data processing system, and a computer program product to identify obstructions (e.g. dirt, debris, frost/ice, bird nest etc.) on a heat sink. Sensors are positioned on a plurality sides of the heat sink fins. The sensors measure the level of reflected light over the plurality of parallel fins exterior surface to determine the amount of obstruction/debris present. Based on the measured level the reflected light as measured by the sensor, an obstruction level of the heat sink is determined by the control unit. If the obstruction level of the heat sink exceeds an obstruction threshold, an alert is generated. An alert can be any alert that notifies the user of the blockage, such as, but not limited to, an audible alarm, a visual alarm, an e-mail, a text short message system message, or other textual alert sent to the user.

Further, heat-dissipating obstruction detection system sends a signal to the active cooling device to increase the active cooling, for example, to the fan to throttle up the speed to maintain the effectivity of advanced cooling. The heat-dissipating obstruction detection system will also send a second alert to the user to come and service the lighting fixture when the obstruction/debris has reached beyond the point where it cannot be cleaned by the active cooling device (e.g. fan). For example, the heat-dissipating obstruction detection system will continue to check the heat-sink for obstructions after reaching the obstruction threshold, and after a predetermine time or number of iterations, if the obstruction remains, it will send the second alert to the user.

The plurality of fins 12 can also have a thermostat 22 coupled on one or more of the fins. The thermostat 22 is in communication with the driver 24 and once a predetermined temperature is reached on a fin, it signals the driver to throttle back the driver current to reduce light output of luminaire 50, or it sends a signal to the active cooling unit/fan 40 to increase the fan speed. Alternatively, sensor 20 send a signal to driver 40 to throttle back the driver current and thereby dim the light output of luminaire 40, and/or, signaling user that service of luminaire 50 is needed. For example, a NTE Electronics NTE-DTC100 Snap Action Disc Thermostat, can be used.

It is appreciated that the heat sink obstruction detection system described in the illustrative embodiments can be employed in any environment where an obstruction detection may be useful. While the illustrative embodiments describe the heat sink obstruction detection system for use with an integrated circuit, the heat sink obstruction detection system can also be utilized in applications such as, for example, but not limited to, refrigeration, heat engines, electronic devices, mechanical devices, and lasers.

In the event that obstruction of the heat sink's fin apertures exceeds alert threshold, control unit 30 generates an alert. The alert is a notification to the user that the current blockage level exceeds acceptable limits as specified by the alert threshold.

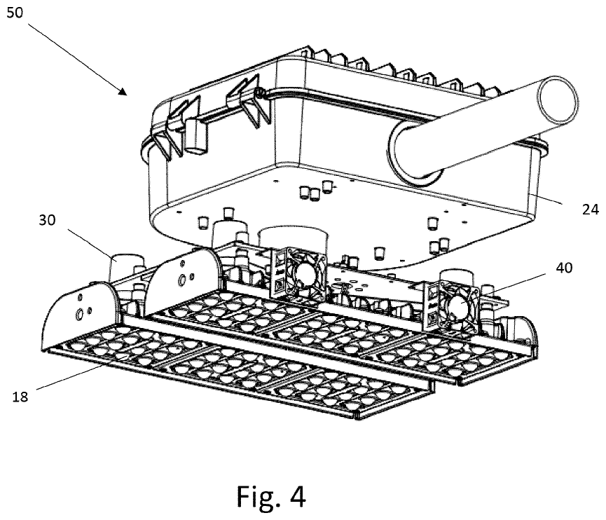

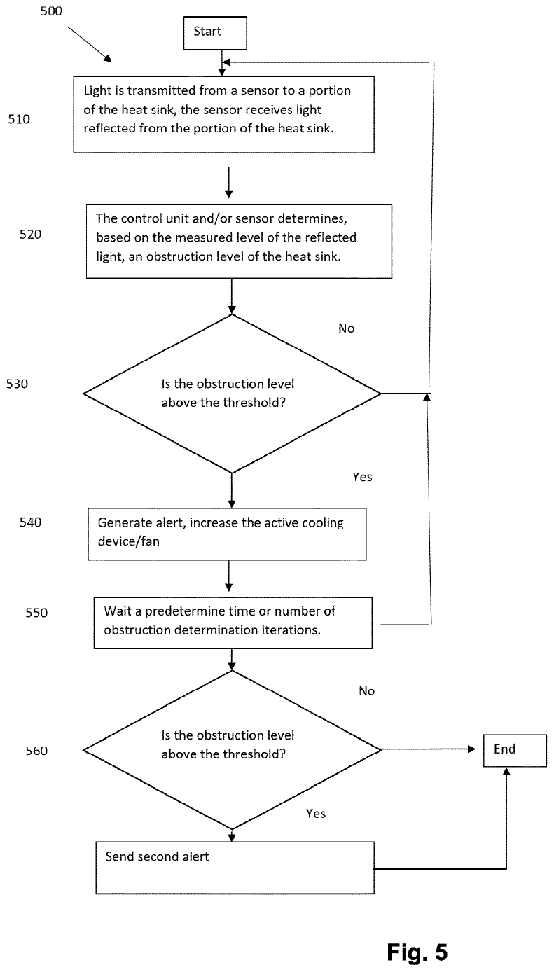

FIG. 4 is a lighting device/luminaire 50 to which the heat-dissipating obstruction detection system is coupled to. The luminaire 50 includes a plurality of LEDs 18, a control unit 18, fans 40 and a driver 24.

Referring now to FIG. 5, a flow chart for determining a heat sink obstruction is shown according to an illustrative embodiment. Process 500 is a software or firmware process, executing on a software or hardware component, such as control unit 30 of FIG. 4.

Process 500 begins by the sensor 20 transmitting light to a portion of the heat sink, the sensor 20 then receives light reflected from the portion of the heat sink. The received light is a measure of the level of reflected light over the plurality of parallel fins exterior surface (step 510).

Responsive to receiving the reflected light, the control unit 30 and/or sensor 20 determines, based on the measured level of the reflected light as measured by the sensor, an obstruction level of the heat sink (step 520).

If the obstruction level of the heat sink exceeds an obstruction threshold (step 530), an alert is generated (step 540).

The reflected light without an obstruction is measured, for example when installed. Therefore, a baseline for the received electrical signal is easily established. When the sensor 20 detects the reflected light, deviation from that baseline is extrapolated to determine the amount of obstruction within the collinear apertures of the heat sink's fins.

Responsive to determining an obstruction level based on the reflected light, process 500 whether the obstruction level is above the blockage threshold (step 530). As more deposits of dust, lint, dirt and other debris accumulate within the collinear apertures of the heat sink's fins, the determined obstruction level of the reflected light as detected by the sensor increases from a baseline amount. The obstruction threshold specifies the level of acceptable blockage of the heat sink.

Responsive to determining that the blockage level is above the obstruction threshold (“yes” at step 530), process 500 generates an alert. As previously noted, the alert is a notification, according to various alert methods, to the user that the obstruction threshold has been exceeded. In addition to or alternatively, the control unit 30 sends a signal to the active cooling device/fan 40 to increase the active cooling, for example, to the fan to throttle up the speed to maintain the effectivity of advanced cooling.

Once the control unit 30 sends the signal to the active cooling device/fan 40 to increase the active cooling, the system waits a predetermined time period, for example two hours and then proceeds back to step 510 to recheck if the obstruction threshold remains. Alternatively, the system can proceed back to step 510 and repeat checking for obstructions a predetermined number of time, for example, 10 iterations.

Responsive to determining that the blockage level is still above the obstruction threshold (“yes” at step 560), process 500 generates a second alert. As previously noted, the alert is a notification, according to various alert methods, to the user that the obstruction threshold has been exceeded and still remains after the active cooling device/fan has been increased. Accordingly the system provides the second alert to inform the user that the device is in need of service for debris or obstruction removal.

Responsive to determining that the blockage level is below the obstruction threshold (“no” at step 560), process 500 ends.

While several inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B,” when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03. It should be understood that certain expressions and reference signs used in the claims pursuant to Rule 6.2(b) of the Patent Cooperation Treaty (“PCT”) do not limit the scope.

1. A method for identifying blockages in a heat sink, the method comprising:
sending, from a sensor or light source, a light signal onto a portion of a heat sink;
receiving, in the sensor, a reflected light signal from the portion of the heat sink;
responsive to receiving the reflected light signal in a control unit, determining an obstruction level of the heat sink based on the reflected light signal;
providing a first alert if the obstruction level is over a predetermined threshold, wherein the alert includes providing a signal to an active cooling system if the obstruction level is over the predetermined threshold, and wherein the signal instructs the active cooling system to increase active cooling, and
after the active cooling system has been increased, waiting a predetermine time or number of obstruction determination iterations, determining if the obstruction level remains over the predetermined threshold, and if so, sending a second alert.

2. The method of claim 1, wherein the heat sink comprises a plurality of fins, and a plurality of channels, the method further comprising:
providing the sensor along at least one of the plurality of channels; and
directing the light signal such that the light signal traverses through at least one of plurality of channels.

3. The method of claim 1 wherein the sensor is selected from the group consisting of a photoconductive device, a photovoltaic, a photodiode, or a phototransistor.

4. The method of claim 1, wherein the first and second alerts include one or more of an audible alarm, a visual alarm, an e-mail, and a text message, to a user.

5. A system for identifying blockages in a heat sink comprising:
a processor having a stored computer usable program code for identifying obstructions in a heat sink of the system;
an active cooling system coupled to the heat sink;
a sensor or light source that transmits a light signal onto a portion of the heat sink and the sensor receives a reflected light signal from the portion of the heat sink; and
wherein the processor unit executes the computer usable program code to receive the reflected light signal from the sensor, determine an obstruction level of the heat sink based on the reflected light signal, provide a first alert if the obstruction level is over a predetermined threshold, wherein the alert includes providing a signal to the active cooling system if the obstruction level is over the predetermined threshold, wherein the signal instructs the active cooling system to increase active cooling, and after the active cooling system has been increased, waiting a predetermine time or number of obstruction determination iterations, determine if the obstruction level remains over the predetermined threshold, and if so, provide a second alert.

6. The system of claim 5, wherein the heat sink comprises a plurality of fins, and a plurality of channels, the sensor is coupled along at least one of the plurality of channels; and the light signal traverses through at least one of plurality of channels.

7. The system of claim 5 wherein the sensor is selected from the group consisting of a photoconductive device, a photovoltaic, a photodiode, or a phototransistor.

8. The system of claim 5, wherein the first and second alerts include one or more of an audible alarm, a visual alarm, an e-mail, and a text message, to a user.

9. The system of claim 6, wherein the system is a luminaire.

10. The system of claim 6, wherein the system further includes a plurality of LEDs, and a driver.

11. The system of claim 10, wherein the system further includes a thermostat coupled on one or more of the plurality of fins, wherein the thermostat is in communication with the driver and/or control unit and once a predetermined temperature is reached on a fin, a signal is sent to the driver to reduce driver current and thereby reduce light output of luminaire, and/or the thermostat sends a signal to the active cooling system to increase active cooling.

12. The system of claim 10, wherein the sensor and/or control unit is in communication with the driver and the first and/or second alert includes a signal to the driver to reduce driver current and thereby reduce light output of luminaire.
